(19) United States
(12) Patent Application Publication
(10) Pub. No.: US 2015/0171883 A1
(43) Pub. Date: Jun. 18, 2015

(54) APPARATUS AND METHOD FOR GENERATING SINUSOIDAL WAVES, AND SYSTEM FOR DRIVING PIEZO ACTUATOR USING THE SAME

(71) Applicant: SAMSUNG ELECTRO-MECHANICS CO., LTD., Suwon-Si (KR)

(72) Inventor: Gyu Won KIM, Suwon-Si (KR)

(73) Assignee: SAMSUNG ELECTRO-MECHANICS CO., LTD., Suwon-Si (KR)

(21) Appl. No.: 14/204,893

(22) Filed: Mar. 11, 2014

(30) Foreign Application Priority Data
Dec. 17, 2013 (KR) 10-2013-0156991

(51) Int. Cl. H03M 1/12; H03M 1/00; H02N 2/00

(52) U.S. Cl. CPC H03M 1/1245; H02N 2/008; H03M 1/001

(57) ABSTRACT

There are provided an apparatus and a method for generating sinusoidal waves, and a system for driving a piezo actuator using the same. The apparatus for generating sinusoidal waves includes: a look-up table storage unit storing a look-up table including a plurality of sampling points, determined based on a base frequency and a sampling frequency; a sinusoidal wave generating unit calculating an integer ratio of a target frequency to the base frequency and obtaining sampling points from the look-up table by reflecting the integer ratio; and a sampling point correction unit determining whether sampling points obtained by the sinusoidal wave generating unit correspond to sampling points corresponding to the maximum and minimum levels of a predetermined sinusoidal wave, to correct the sampling points obtained by the sinusoidal wave generating unit.

### CROSS-REFERENCE TO RELATED APPLICATION

This application claims the benefit of Korean Patent Application No. 10-2013-0156991 filed on Dec. 17, 2013, with the Korean Intellectual Property Office, the disclosure of which is incorporated herein by reference.

### BACKGROUND

The present disclosure relates to an apparatus and a method for generating sinusoidal waves, and a system for driving a piezo actuator using the same.

As electronic device technology advances, various driving apparatuses are being developed, and various types of wave are being used for driving such driving apparatuses. In particular, in haptic technology elements commonly used in touch-operated devices such as mobile terminals, precise responses to user inputs are important.

In the field of haptic technology, a piezo actuator, driven with a sinusoidal wave, is commonly used, and accordingly, it is necessary to generate the waveform of the sinusoidal wave more precisely in order to drive the piezo actuator with precision. In order to generate a sinusoidal wave precisely, a look-up table having high-resolution digital values stored therein and a high-resolution digital-to-analog converter are used. Since the digital values stored in the look-up table are determined based on a base frequency and a sampling frequency, when a target frequency a user desires is greatly increased, the peak value of a sinusoidal wave may deviate from the target frequency.

### RELATED ART DOCUMENT

(Patent Document 1) Korean Patent Laid-Open Publication No. 2001-0033383

### SUMMARY

An aspect of the present disclosure may provide an apparatus and a method for generating sinusoidal waves capable of precisely generating a sinusoidal wave by determining whether sampling points, determined based on a base frequency and a target frequency correspond to sampling points corresponding to the maximum and minimum levels of the sinusoidal wave, and a system for driving a piezo actuator using the same.

According to an aspect of the present disclosure, an apparatus for generating sinusoidal waves may include: a look-up table storage unit storing a look-up table including a plurality of sampling points, determined based on a base frequency and a sampling frequency; a sinusoidal wave generating unit calculating an integer ratio of a target frequency to the base frequency and obtaining sampling points from the look-up table by reflecting the integer ratio; and a sampling point correction unit determining whether sampling points obtained by the sinusoidal wave generating unit correspond to sampling points corresponding to the maximum and minimum levels of a predetermined sinusoidal wave, to correct the sampling points obtained by the sinusoidal wave generating unit, wherein the sinusoidal wave generating unit generates a sinusoidal wave based on the sampling points corrected by the sampling point correction unit.

The number of sampling points included in the look-up table may correspond to an integer calculated by dividing the sampling frequency by the base frequency.

The sinusoidal wave generating unit may calculate the integer ratio by dividing the target frequency by the base frequency.

The sinusoidal wave generating unit may obtain every n^{th} sampling point from among the plurality of sampling points in the look-up table in the case that the integer ratio is n.

The sampling point correction unit may not change the sampling points obtained by the sinusoidal wave generating unit if at least one of the sampling points obtained by the sinusoidal wave generating unit corresponds to a sampling point corresponding to the maximum level of the predetermined sinusoidal wave, and if at least one of the sampling points obtained by the sinusoidal wave generating unit corresponds to a sampling point corresponding to the minimum level of the predetermined sinusoidal wave.

The sampling point correction unit may change at least one of the sampling points obtained by the sinusoidal wave generating unit into a sampling point corresponding to the maximum level of the predetermined sinusoidal wave if none of the sampling points obtained by the sinusoidal wave generating unit corresponds to a sampling point corresponding to the maximum level of the predetermined sinusoidal wave.

The sampling point correction unit may change a sampling point having a highest analog level among the sampling points obtained by the sinusoidal wave generating unit.

The sampling point correction unit may change a sampling point having a digital level closest to that of the sampling point corresponding to the maximum level of the predetermined sinusoidal wave among the sampling points obtained by the sinusoidal wave generating unit.

The sampling point correction unit may change at least one of the sampling points obtained by the sinusoidal wave generating unit into a sampling point corresponding to the minimum level of the predetermined sinusoidal wave if none of the sampling points obtained by the sinusoidal wave generating unit corresponds to a sampling point corresponding to the minimum level of the predetermined sinusoidal wave.

The sampling point correction unit may change a sampling point having a lowest analog level among the sampling points obtained by the sinusoidal wave generating unit.

The sampling point correction unit may change a sampling point having a digital level closest to that of the sampling point corresponding to the minimum level of the predetermined sinusoidal wave among the sampling points obtained by the sinusoidal wave generating unit.

The sinusoidal wave generating unit may include: a calculation unit calculating the integer ratio and obtaining sampling points from the look-up table according to the integer ratio; a digital-to-analog converter converting digital values of the sampling points corrected by the sampling point correction unit into analog values; and an amplifier filtering the analog values.

According to another aspect of the present disclosure, a method of generating sinusoidal waves may include: receiving a target frequency; obtaining a plurality of sampling points from a look-up table according to an integer ratio calculated based on the target frequency and a base frequency; correcting the obtained sampling points by comparing the obtained sampling points with sampling points corresponding to maximum and minimum levels of a predetermined sinusoidal wave; and generating a sinusoidal wave based on the corrected sampling points.

The number of sampling points included in the look-up table may correspond to an integer calculated by dividing a sampling frequency by the base frequency.

The sinusoidal wave generating unit may obtain every n^{th} sampling point from among the plurality of sampling points in the look-up table in the case that the integer ratio is n.

The correcting of the obtained sampling points may include not changing the sampling points obtained by the sinusoidal wave generating unit if at least one of the sampling points obtained by the sinusoidal wave generating unit corresponds to a sampling point corresponding to the maximum level of the predetermined sinusoidal wave, and if at least one of the sampling points obtained by the sinusoidal wave generating unit corresponds to a sampling point corresponding to the minimum level of the predetermined sinusoidal wave.

The correcting of the obtained sampling points may include changing one of the obtained sampling points at a sampling point corresponding to the maximum level of the predetermined sinusoidal wave if none of the obtained sampling points corresponds to a sampling point corresponding to the maximum level of the predetermined sinusoidal wave.

The correcting of the obtained sampling points may include changing a sampling point having a highest analog level among the obtained sampling points.

The correcting of the obtained sampling points may include changing a sampling point having a digital level closest to that of the sampling point corresponding to the maximum level of the predetermined sinusoidal wave among the obtained sampling points.

The correcting of the obtained sampling points may include changing one of the obtained sampling points at a sampling point corresponding to the minimum level of the predetermined sinusoidal wave if none of the obtained sampling points corresponds to a sampling point corresponding to the minimum level of the predetermined sinusoidal wave among the obtained sampling points.

The correcting of the obtained sampling points may include changing a sampling point having a lowest analog level among the obtained sampling points.

The correcting of the obtained sampling points may include changing a sampling point having a digital level closest to that of the sampling point corresponding to the minimum level of the predetermined sinusoidal wave among the obtained sampling points.

The correcting of the obtained sampling points may be performed for every period of the predetermined sinusoidal wave.

According to another aspect of the present disclosure, a system for driving a piezo actuator may include: a piezo actuator operated by receiving a sinusoidal wave in both terminals thereof; and the apparatus for generating sinusoidal waves as described above.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a system for driving a piezo actuator according to an exemplary embodiment of the present disclosure;

FIG. 2 is a block diagram of an example of an apparatus for generating sinusoidal waves employed in the system for driving a piezo actuator;

FIG. 3 is a block diagram showing the system for driving a piezo actuator shown in FIG. 1 in more detail; and

FIG. 4 is a flowchart illustrating a method of generating sinusoidal waves according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

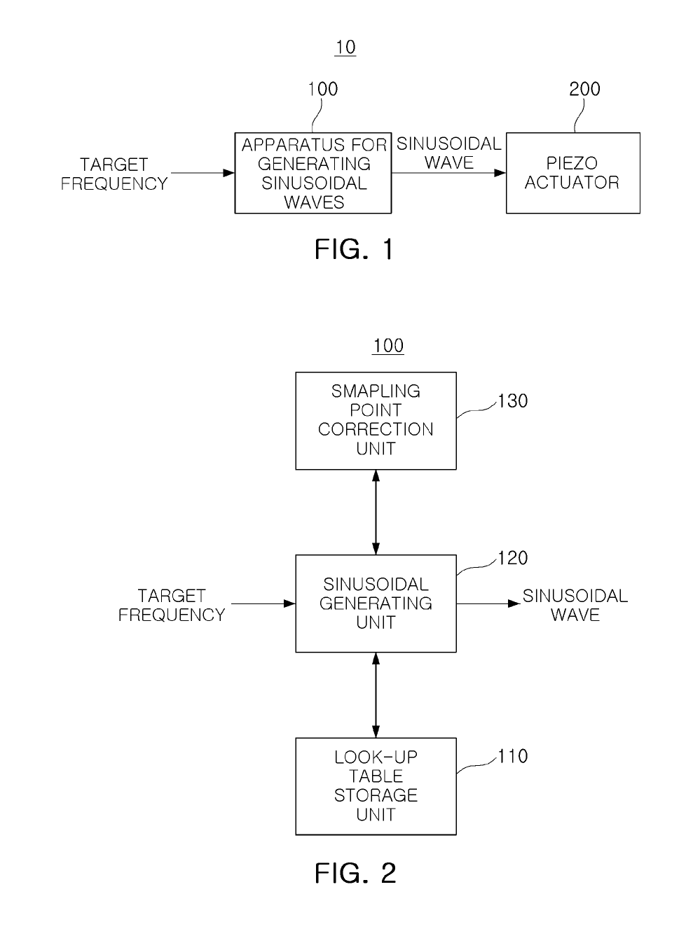

FIG. 1 is a block diagram of a system for driving a piezo actuator according to an exemplary embodiment of the present disclosure.

Referring to FIG. 1, the system 10 for driving a piezo actuator may include an apparatus for generating sinusoidal waves 100 and a piezo actuator 200.

The apparatus for generating sinusoidal waves 100 may generate sinusoidal waves to drive the piezo actuator 200 and may provide it to the piezo actuator 200. Accordingly, the apparatus for generating sinusoidal waves 100 may serve as an apparatus for driving the piezo actuator 200.

Upon receiving a target frequency for a sinusoidal wave to be generated, the apparatus for generating sinusoidal waves 100 may generate a sinusoidal wave at the target frequency.

The apparatus for generating sinusoidal waves 100 may generate sinusoidal waves using a look-up table. The look-up table may include a plurality of sampling points, determined based on a base frequency and a predetermined sampling frequency.

For example, in the case that the base frequency is 7.8125 Hz and the predetermined sampling frequency is 8 KHz, there may be 1,024 sampling points. In this case, in the case that the target frequency is 8 KHz, values corresponding to 1,024 sampling points are obtained, and analog values (e.g., current values) corresponding to the values are output, thereby generating a sinusoidal wave.

That is, the apparatus for generating sinusoidal waves 100 may obtain the sampling points using a look-up table having digital values stored therein, and then perform digital-analog conversion to thereby generate a sinusoidal wave.

The apparatus for generating sinusoidal waves 100 may determine whether the sampling points selected based on the target frequency correspond to predetermined maximum and minimum levels of the sinusoidal wave and, if not, may change the sampling points selected based on the target frequency so as to generate a sinusoidal wave. The piezo actuator 200 may be operated by receiving at both terminals thereof the sinusoidal wave from the apparatus for generating sinusoidal waves 100.

FIG. 2 is a block diagram of an example of an apparatus for generating sinusoidal waves employed in the system for driving a piezo actuator. Referring to FIG. 2, the apparatus for generating sinusoidal waves 100 may include a look-up table storage unit 110, a sinusoidal wave generating unit 120, and a sampling point correction unit 130.

The look-up table storage unit 110 may store a look-up table that includes a plurality of sampling points, determined based on the base frequency and sampling frequency. One period of a sinusoidal wave may be generated, based on all of the sampling points stored in the look-up table storage unit 110. Due to the nature of the sinusoidal wave, in the case that the sampling frequency is higher, there may be multiple sampling points corresponding to the maximum level and multiple sampling points corresponding to the minimum level of the sinusoidal wave. In the following description, for convenience of illustration, a sinusoidal wave generated based on all of the sampling points stored in the look-up table storage unit 110 is referred to as a predetermined sinusoidal wave.

The sinusoidal wave generating unit 120 may calculate an integer ratio of the target frequency to the base frequency, may select and obtain sampling points from the look-up table stored in the look-up table storage unit 120 by reflecting the integer ratio, and may output a sinusoidal wave based on digital levels of the obtained sampling points. Specifically, in the case that the integer ratio is n, the sinusoidal wave generating unit 120 may select and obtain every n^{th} sampling point from among the sampling points.

In an exemplary embodiment, sampling points selected and obtained by the sinusoidal wave generating unit 120 at first time may be sampling points stored in the look-up table storage unit 110 at first time among the plurality of sampling point stored in the look-up table storage unit 110.

For example, assuming that the base frequency is 7.8125 Hz, the predetermined sampling frequency is 8 KHz, and the target frequency is 23.4375 KHz, there are 1,024 ((=8000/7.8125) sampling points, and the integer ratio n is 3 (=23.4375/7.8125).

Accordingly, the sinusoidal wave generating unit 120 may select and obtain every third sampling point, e.g., 1st, 4th, 7th sampling point, and so on from among the 1,024 sampling points.

The sampling points obtained by the sinusoidal wave generating unit 120 may be provided to the sampling point correction unit 130, and the sampling point correction unit 130 may determine whether the sampling points obtained by the sinusoidal wave generating unit 120 correspond to the sampling points corresponding to the maximum and minimum levels of the predetermined sinusoidal wave.

The sampling point correction unit 130 may determine whether at least one of the sampling points obtained by the sinusoidal wave generating unit 120 corresponds to the sampling point corresponding to the maximum level of the predetermined sinusoidal wave and to the sampling point corresponding to the minimum level of the predetermined sinusoidal wave. Further, the sampling point correction unit 130 may perform the determining for every period of the predetermined sinusoidal wave.

If at least one of the sampling points obtained by the sinusoidal wave generating unit 120 corresponds to the sampling point corresponding to the maximum level of the predetermined sinusoidal wave, the sampling point correction unit 130 may not change the sampling points.

On the contrary, if at least one of the sampling points obtained by the sinusoidal wave generating unit 120 corresponds to the sampling point corresponding to the maximum level of the predetermined sinusoidal wave, the sampling point correction unit 130 may change one of the obtained sampling points into the sampling point corresponding to the maximum level of the predetermined sinusoidal wave.

In an exemplary embodiment of the present disclosure, the sampling point that is changed into the sampling point corresponding to the maximum level of the predetermined sinusoidal wave may have the highest analog level among the obtained sampling points or may have a digital level closest to the sampling point corresponding to the maximum level.

Similarly, if at least one of the sampling points obtained by the sinusoidal wave generating unit 120 corresponds to the sampling point corresponding to the minimum level of the predetermined sinusoidal wave, the sampling point correction unit 130 may not change the sampling points.

On the contrary, if at least one of the sampling points obtained by the sinusoidal wave generating unit 120 corresponds to the sampling point corresponding to the minimum level of the predetermined sinusoidal wave, the sampling point correction unit 130 may change one of the obtained sampling points into the sampling point corresponding to the minimum level of the predetermined sinusoidal wave.

In an exemplary embodiment of the present disclosure, the sampling point that is changed into the sampling point corresponding to the minimum level of the predetermined sinusoidal wave may have the lowest analog level among the obtained sampling points or may have a digital level closest to the sampling point corresponding to the minimum level.

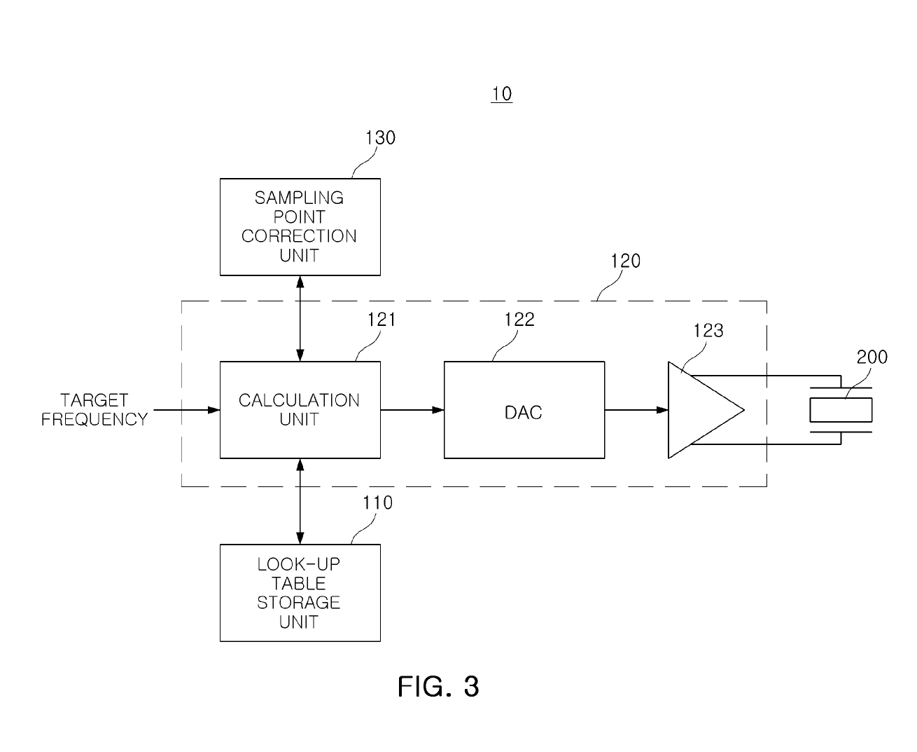

FIG. 3 is a block diagram showing the system for driving a piezo actuator shown in FIG. 1 in more detail. Referring to FIG. 3, the sinusoidal wave generating unit 120 may include a calculation unit 121, a digital-to-analog converter (DAC) 122, and an amplifier 123.

The calculation unit 121 may calculate the integer ratio of the target frequency to the base frequency, and may select and obtain sampling point from the look-up table stored in the look-up table storage unit 110 by reflecting the integer ratio. As mentioned earlier, the sampling points obtained by the calculation unit 121 may be changed by the sampling point correction unit 130.

The DAC 122 may receive digital values of the sampling points obtained by the calculation unit 121 and may change them into analog values to output them.

Upon receiving a digital value, the DAC 122 may select sampling points based on a base frequency so as to output an analog value corresponding to the sampling points corresponding to the target frequency.

The amplifier 122 may filter the analog values output from the DAC 121 to generate a sinusoidal wave and may provide it to the piezo actuator 200.

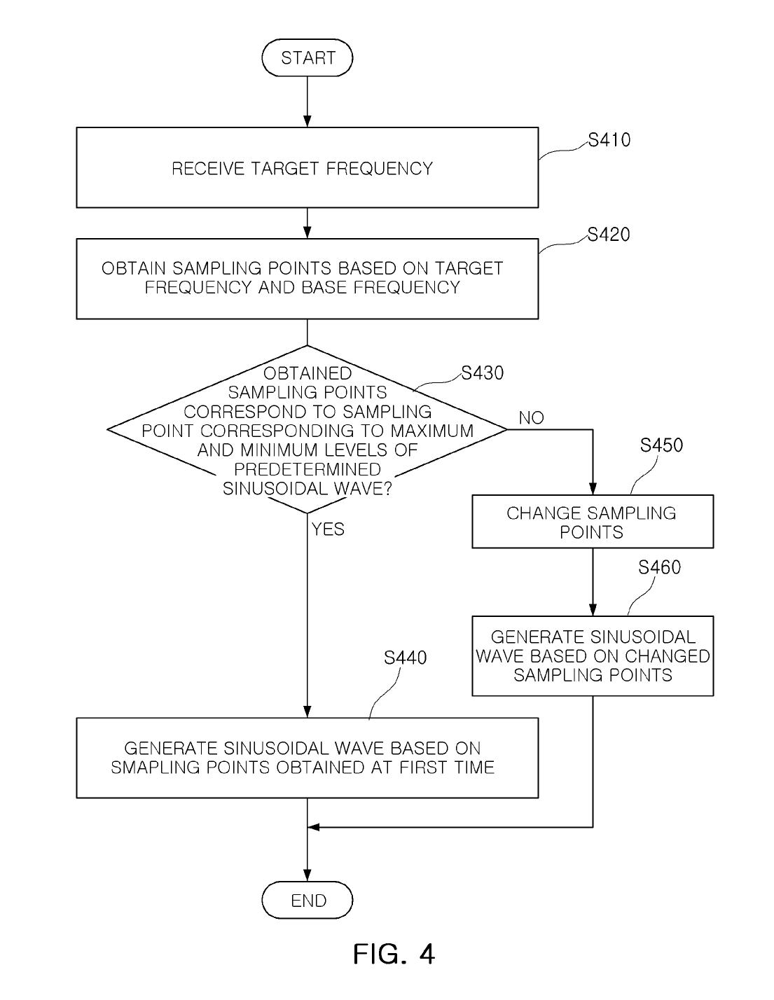

FIG. 4 is a flow chart illustrating a method of generating sinusoidal waves according to an exemplary embodiment of the present disclosure.

The method of generating a sinusoidal wave according to the exemplary embodiment is performed by the apparatus for generating sinusoidal waves 100 described above with reference to FIGS. 1 through 3, and thus redundant descriptions will not be made.

Referring to FIG. 4, the method of generating a sinusoidal wave according to the exemplary embodiment starts with receiving, by the sinusoidal wave generating unit 120, a target frequency (S410). Then, the sinusoidal wave generating unit 120 may obtain sampling points stored in the look-up table storage unit (S420). The sampling point correction unit 130 may determine whether the sampling points obtained by the sinusoidal wave generating unit 120 correspond to the sampling points corresponding to the maximum and minimum levels of a predetermined sinusoidal wave (S430).

In the case that the sampling points obtained by the sinusoidal wave generating unit 120 correspond to the sampling points corresponding to the maximum and minimum levels of the predetermined sinusoidal wave, the sampling point correction unit 130 may not change sampling points obtained at first time, and the sinusoidal wave generating unit 120 may generate a sinusoidal wave based on the sampling points obtained at first time (S440).

On the contrary, in the case that the sampling points obtained by the sinusoidal wave generating unit 120 do not correspond to the sampling points corresponding to the maximum and minimum levels of the predetermined sinusoidal wave, the sampling point correction unit 130 may change at least one of the sampling points obtained by the sinusoidal wave generating unit 120 into the sampling point corresponding to the maximum and minimum levels (S450). Then, the sinusoidal wave generating unit 120 may generate a sinusoidal wave based on the changed sampling points (S460).

As set forth above, according to exemplary embodiments of the present disclosure, a sinusoidal wave can be generated precisely by determining whether sampling points, determined based on a base frequency and a target frequency correspond to sampling points corresponding to the maximum and minimum levels of the sinusoidal wave.

While exemplary embodiments have been shown and described above, it will be apparent to those skilled in the art that modifications and variations could be made without departing from the spirit and scope of the present disclosure as defined by the appended claims.

What is claimed is:

1. An apparatus for generating sinusoidal waves, comprising:
a look-up table storage unit storing a look-up table including a plurality of sampling points, determined based on a base frequency and a sampling frequency;
a sinusoidal wave generating unit calculating an integer ratio of a target frequency to the base frequency and obtaining sampling points from the look-up table by reflecting the integer ratio; and
a sampling point correction unit determining whether sampling points obtained by the sinusoidal wave generating unit correspond to sampling points corresponding to the maximum and minimum levels of a predetermined sinusoidal wave, to correct the sampling points obtained by the sinusoidal wave generating unit, wherein the sinusoidal wave generating unit generates a sinusoidal wave based on the sampling points corrected by the sampling point correction unit.

2. The apparatus of claim 1, wherein the number of sampling points included in the look-up table corresponds to an integer calculated by dividing the sampling frequency by the base frequency.

3. The apparatus of claim 1, wherein the sinusoidal wave generating unit calculates the integer ratio by dividing the target frequency by the base frequency.

4. The apparatus of claim 3, wherein the sinusoidal wave generating unit obtains every n^{th} sampling point from among the plurality of sampling points in the look-up table in the case that the integer ratio is n.

5. The apparatus of claim 1, wherein the sampling point correction unit does not change the sampling points obtained by the sinusoidal wave generating unit if at least one of the sampling points obtained by the sinusoidal wave generating unit corresponds to a sampling point corresponding to the maximum level of the predetermined sinusoidal wave, and if at least one of the sampling points obtained by the sinusoidal wave generating unit corresponds to a sampling point corresponding to the minimum level of the predetermined sinusoidal wave.

6. The apparatus of claim 1, wherein the sampling point correction unit changes at least one of the sampling points obtained by the sinusoidal wave generating unit into a sampling point corresponding to the maximum level of the predetermined sinusoidal wave if none of the sampling points obtained by the sinusoidal wave generating unit corresponds to the sampling point corresponding to the maximum level of the predetermined sinusoidal wave.

7. The apparatus of claim 6, wherein the sampling point correction unit changes a sampling point having a highest analog level among the sampling points obtained by the sinusoidal wave generating unit.

8. The apparatus of claim 6, wherein the sampling point correction unit changes a sampling point having a digital level closest to that of the sampling point corresponding to the maximum level of the predetermined sinusoidal wave among the sampling points obtained by the sinusoidal wave generating unit.

9. The apparatus of claim 1, wherein the sampling point correction unit changes at least one of the sampling points obtained by the sinusoidal wave generating unit into a sampling point corresponding to the minimum level of the predetermined sinusoidal wave if none of the sampling points obtained by the sinusoidal wave generating unit corresponds to the sampling point corresponding to the minimum level of the predetermined sinusoidal wave.

10. The apparatus of claim 9, wherein the sampling point correction unit changes a sampling point having a lowest analog level among the sampling points obtained by the sinusoidal wave generating unit.

11. The apparatus of claim 9, wherein the sampling point correction unit changes a sampling point having a digital level closest to that of the sampling point corresponding to the minimum level of the predetermined sinusoidal wave among the sampling points obtained by the sinusoidal wave generating unit.

12. The apparatus of claim 1, wherein the sinusoidal wave generating unit includes:
a calculation unit calculating the integer ratio and obtaining sampling points from the look-up table according to the integer ratio;
a digital-to-analog converter converting digital values of the sampling points corrected by the sampling point correction unit into analog values; and
an amplifier filtering the analog values.

13. A method of generating sinusoidal waves, comprising:
receiving a target frequency;
obtaining a plurality of sampling points from a look-up table according to an integer ratio calculated based on the target frequency and a base frequency;
correcting the obtained sampling points by comparing the obtained sampling points with sampling points corresponding to maximum and minimum levels of a predetermined sinusoidal wave; and
generating a sinusoidal wave based on the corrected sampling points.

14. The method of claim 13, wherein the number of sampling points included in the look-up table corresponds to an integer calculated by dividing a sampling frequency by the base frequency.

15. The method of claim 14, wherein obtaining of the plurality of sampling points includes obtaining every n^{th} sampling point from among the plurality of sampling points in the look-up table in the case that the integer ratio is n.

16. The method of claim 13, wherein the correcting of the obtained sampling points includes not changing the sampling points obtained by the sinusoidal wave generating unit if at least one of the sampling points obtained by the sinusoidal wave generating unit corresponds to a sampling point corresponding to the maximum level of the predetermined sinusoidal wave, and if at least one of the sampling points obtained by the sinusoidal wave generating unit corresponds to a sampling point corresponding to the minimum level of the predetermined sinusoidal wave.

17. The method of claim 13, wherein the correcting of the obtained sampling points includes changing one of the obtained sampling points at a sampling point corresponding to the maximum level of the predetermined sinusoidal wave if none of the obtained sampling points corresponds to the sampling point corresponding to the maximum level of the predetermined sinusoidal wave.

18. The method of claim 17, wherein the correcting of the obtained sampling points includes changing a sampling point having a highest analog level among the obtained sampling points.

19. The method of claim 17, wherein the correcting of the obtained sampling points includes changing a sampling point having a digital level closest to that of the sampling point corresponding to the maximum level of the predetermined sinusoidal wave among the obtained sampling points.

20. The method of claim 13, wherein the correcting of the obtained sampling points includes changing one of the obtained sampling points at a sampling point corresponding to the minimum level of the predetermined sinusoidal wave if none of the obtained sampling points corresponds to the sampling point corresponding to the minimum level of the predetermined sinusoidal wave among the obtained sampling points.

21. The method of claim 20, wherein the correcting of the obtained sampling points includes changing a sampling point having a lowest analog level among the obtained sampling points.

22. The method of claim 20, wherein the correcting of the obtained sampling points includes changing a sampling point having a digital level closest to that of the sampling point corresponding to the minimum level of the predetermined sinusoidal wave among the obtained sampling points.

23. The method of claim 13, wherein the correcting of the obtained sampling points is performed for every period of the predetermined sinusoidal wave.

24. A system for driving a piezo actuator, comprising:
a piezo actuator operated by receiving a sinusoidal wave in both terminals thereof; and
the apparatus for generating sinusoidal waves of claim 1.
